(19) United States
(12) Patent Application Publication
(10) Pub. No.: US 2014/0246226 A1
(43) Pub. Date: Sep. 4, 2014

(54) METHOD OF FABRICATING COPPER-NICKEL MICRO MESH CONDUCTORS

(71) Applicants: Danliang Jin, The Woodlands, TX (US); Ed S. Ramakrishnan, Spring, TX (US); Robert J. Petcavich, The Woodlands, TX (US)

(72) Inventors: Danliang Jin, The Woodlands, TX (US); Ed S. Ramakrishnan, Spring, TX (US); Robert J. Petcavich, The Woodlands, TX (US)

(73) Assignee: Uni-Pixel Displays, Inc., The Woodlands, TX (US)

(21) Appl. No.: 13/784,643

(22) Filed: Mar. 4, 2013

(51) Int. Cl. H05K 1/09; H05K 3/12

(52) U.S. Cl. CPC H05K 1/092; H05K 3/12
USPC 174/257; 427/97.3

(57) ABSTRACT

A method of fabricating copper-nickel mesh conductors includes printing a patterned ink seed layer on a substrate. Electroless copper is plated on the printed patterned ink seed layer. A predetermined thickness of electroless nickel is plated on the plated electroless copper.

### BACKGROUND OF THE INVENTION

An electronic device with a touch screen allows a user to control the device by touch. The user may interact directly with the objects depicted on the display through touch or gestures. Touch screens are commonly found in consumer, commercial, and industrial devices including smartphones, tablets, laptop computers, desktop computers, monitors, gaming consoles, and televisions. A touch screen includes a touch sensor that conveys touch information to the device.

Conventional touch sensors use indium tin oxide (“ITO”) conductors. Industry estimates suggest that the increased production of touch sensors may exhaust worldwide reserves of the rare Earth metal indium within the decade. Because of the scarce supply, high demand, and foreign control of indium reserves, ITO is expensive to source, subject to price volatility, and represents a significant supply chain risk to manufacturers.

In addition to scarcity and price concerns, ITO is difficult and expensive to work with. Because of the difficulty of depositing ITO on a substrate, an expensive sputtering process is required to fabricate ITO-based touch sensors. From a performance standpoint, ITO suffers from high electrical resistivity and mechanical brittleness. The high electrical resistivity of ITO conductors contributes to increased power consumption and increased scan rate latency. Because ITO is brittle, ITO-based touch sensors are subject to low yield, high defect rates, and are constrained to small physical dimensions.

### BRIEF SUMMARY OF THE INVENTION

According to one aspect of one or more embodiments of the present invention, a method of fabricating copper-nickel micro mesh conductors includes printing a patterned ink seed layer on a substrate. Electroless copper is plated on the printed patterned ink seed layer. A predetermined thickness of electroless nickel is plated on the plated electroless copper.

According to one aspect of one or more embodiments of the present invention, a touch sensor includes a substrate and a patterned ink seed layer printed on the substrate. An electroless copper plating layer is disposed on the printed patterned ink seed layer. An electroless nickel plating layer, having a predetermined thickness, is disposed on the electroless copper plating layer.

Other aspects of the present invention will be apparent from the following description and claims.

### BRIEF DESCRIPTION OF THE DRAWINGS

FIG. 1 shows a stack up of a touch screen in accordance with one or more embodiments of the present invention.

FIG. 2 shows a touch sensor in accordance with one or more embodiments of the present invention.

FIG. 3 shows a method of fabricating copper-nickel micro mesh conductors in accordance with one or more embodiments of the present invention.

FIG. 4 shows a cross-section of a copper-nickel micro mesh conductor in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

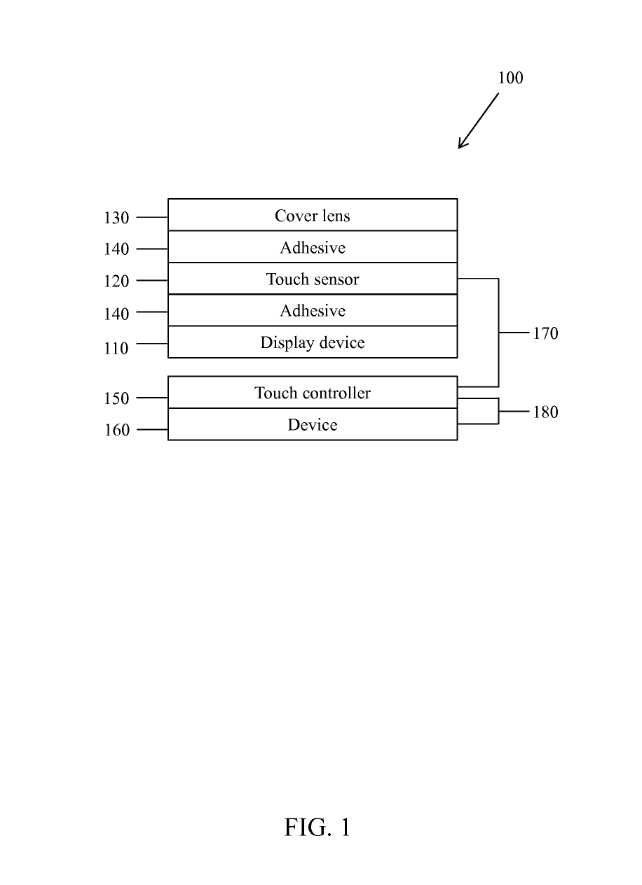

FIG. 1 shows a touch screen in accordance with one or more embodiments of the present invention. Touch screen 100 includes display device 110 configured to output a visual display of information. In one or more embodiments of the present invention, display device 110 may be a conventional liquid crystal display (“LCD”) screen. Touch sensor 120 is attached to display device 110 by a transparent adhesive layer 140. In one or more embodiments of the present invention, an optional cover lens 130 may be attached to touch sensor 120 by a transparent adhesive layer 140. Touch sensor 120 is a transparent conductive layer that inputs touch information to touch controller 150 through electrical connection 170. In one or more embodiments of the present invention, touch sensor 120 may include a plurality of copper-nickel conductors arranged in a micro mesh (not independently shown). In one or more embodiments of the present invention, the plurality of copper-nickel conductors may be arranged in perpendicular rows and columns to form a co-planar micro mesh grid (not independently shown). One of ordinary skill in the art will recognize that other arrangements of copper-nickel micro mesh conductors are within the scope of one or more embodiments of the present invention. A current is applied to the micro mesh creating an electrostatic field. When an object, such as a finger or stylus, comes into contact with the touch screen 100, the electrostatic field is distorted at the location of the touch. Touch controller 150 senses the distortion at the location of the touch and conveys touch information to a device 160 by an electrical connection 180.

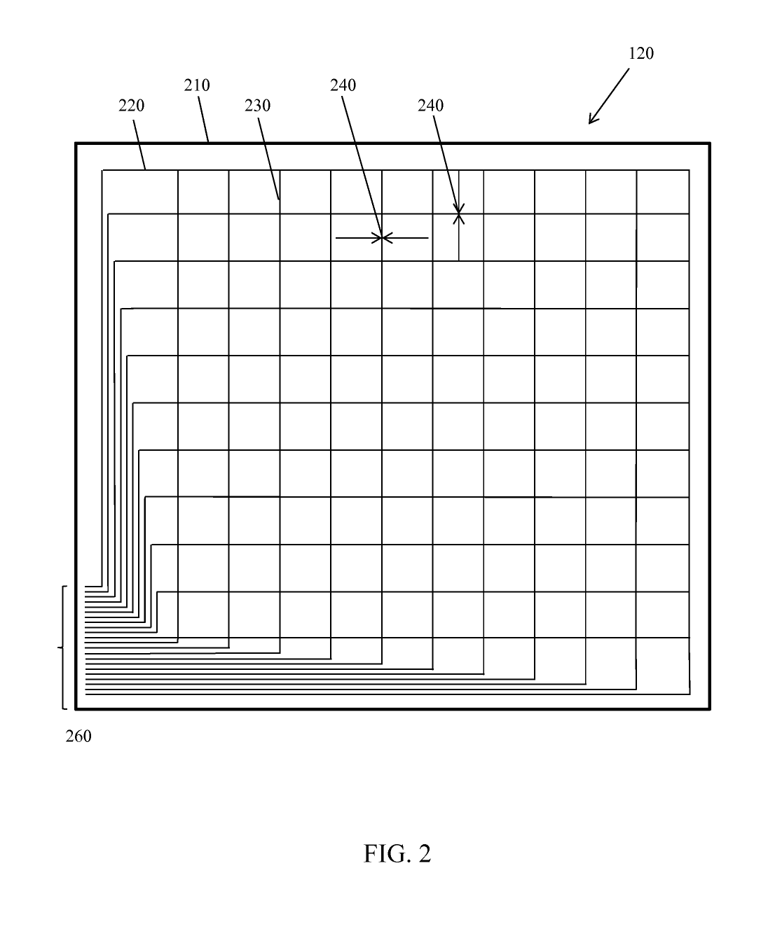

FIG. 2 shows a touch sensor in accordance with one or more embodiments of the present invention. Touch sensor 120 includes a transparent substrate 210. Transparent substrate 210 allows for the transmission of light with a transmittance rate of 90% or more. Transparent substrate 210 may be flexible and is suitable for receiving a printed patterned ink seed layer. A patterned ink seed layer may be printed on transparent substrate 210 by a printing process. In one or more embodiments of the present invention, a plurality of copper conductors are disposed on the printed patterned ink seed layer by an electroless plating process. In one or more embodiments of the present invention, a plurality of nickel conductors are disposed on the plated electroless copper conductors by an electroless nickel plating process. In one or more embodiments of the present invention, the copper-nickel conductors may be arranged in a micro mesh of row conductors 220 and column conductors 230 co-planar and perpendicular to one another. One of ordinary skill in the art will recognize that other network configurations or patterns of copper-nickel conductors are within the scope of one or more embodiments of the present invention. In one or more embodiments of the present invention, touch sensor 120 may be sized to provide touch sensor coverage to the visible screen area of a display device.

The row conductors 220 and column conductors 230 are configured to interface with a touch controller (150 of FIG. 1) through interface 260. In one or more embodiments of the present invention, interface 260 serves as the interface between row conductors 220, column conductors 230, and touch controller (150 of FIG. 1). One of ordinary skill in the art will recognize that the configuration, break out, and routing of interface 260 may vary in accordance with one or more embodiments of the present invention.

In one or more embodiments of the present invention, a width of the copper-nickel micro mesh conductors may be varied in accordance with an application. In one or more embodiments of the present invention, the width 240 of the copper-nickel micro mesh conductors may be in the range of 1 micron to 9 microns. In one or more embodiments of the present invention, the width 240 of the copper-nickel micro mesh conductors may be in a range of 10 microns to 20 microns. In one or more embodiments of the present invention, the width 240 of the copper-nickel micro mesh conductors may be greater than 20 microns.

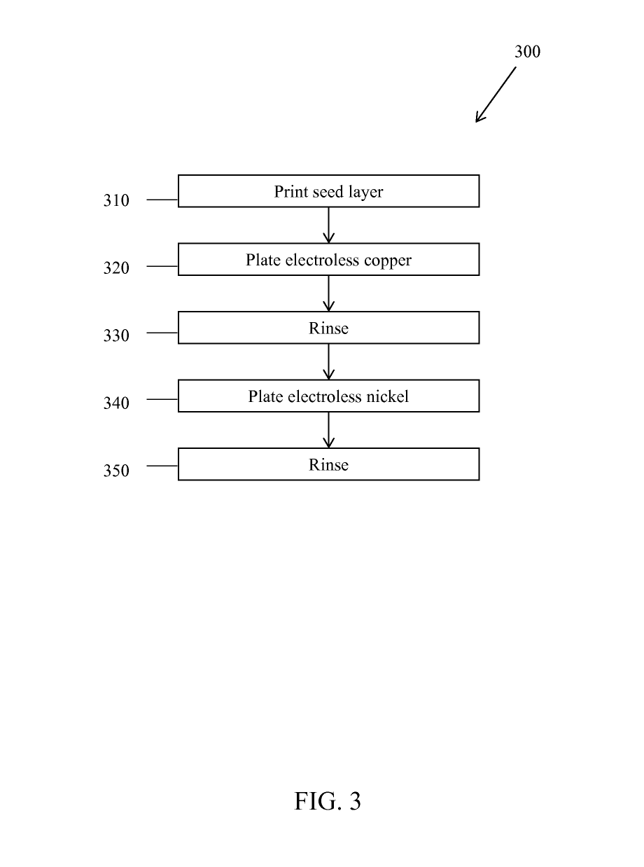

FIG. 3 shows a method of fabricating copper-nickel micro mesh conductors in accordance with one or more embodiments of the present invention. In step 310, a patterned ink seed layer may be printed on a substrate. In one or more embodiments of the present invention, the substrate may be transparent. In one or more embodiments of the present invention, the substrate may be opaque. In one or more embodiments of the present invention, the substrate may polyethylene terephthalate (“PET”). In one or more embodiments of the present invention, the substrate may be polyethylene naphthalate (“PEN”). In one or more embodiments of the present invention, the substrate may be cellulose acetate (“TAC”). In one or more embodiments of the present invention, the substrate may be linear low-density polyethylene (“LLDPE”). In one or more embodiments of the present invention, the substrate may be bi-axially-oriented polypropylene (“BOPP”). In one or more embodiments of the present invention, the substrate may be a polyester substrate. In one or more embodiments of the present invention, the substrate may be a polypropylene substrate. In one or more embodiments of the present invention, the substrate may be a thin glass substrate. One of ordinary skill in the art will recognize that other substrates are within the scope of one or more embodiments of the present invention.

In one or more embodiments of the present invention, the patterned ink seed layer may be printed on the substrate with a printing process suitable for printing seed conductors with micron-fine widths or features. In one or more embodiments of the present invention, the patterned ink seed layer may be printed on the substrate with an inkjet printing process. In one or more embodiments of the present invention, the patterned ink seed layer may be printed on the substrate with a screen printing process. In one or more embodiments of the present invention, the patterned ink seed layer may be printed on the substrate with an offset printing process. In one or more embodiments of the present invention, the patterned ink seed layer may be printed on the substrate with a gravure printing process. In one or more embodiments of the present invention, the patterned ink seed layer may be printed on the substrate with a flexographic printing process.

In one or more embodiments of the present invention, the patterned ink seed layer may be printed on the substrate with a printing process suitable for printing seed conductors with micron-fine widths or features as disclosed in co-pending PCT International Application Serial No. PCT/US12/61787, filed on Oct. 25, 2012, which claims priority to U.S. Provisional Patent Application Ser. No. 61/551,071, filed on Oct. 25, 2011, which is hereby incorporated by reference. In one or more embodiments of the present invention, the patterned ink seed layer may be printed on the substrate with a printing process suitable for printing seed conductors with micron-fine widths or features as disclosed in co-pending PCT International Application Serial No. PCT/US12/61575, filed on Oct. 24, 2012, which claims priority to U.S. Provisional Patent Application Ser. No. 61/551,109, filed on Oct. 25, 2011, which is hereby incorporated by reference. In one or more embodiments of the present invention, the patterned ink seed layer may be printed on the substrate with a printing process suitable for printing seed conductors with micron-fine widths or features as disclosed in co-pending U.S. Provisional Patent Application Ser. No. 61/657,942, filed on Jun. 11, 2012, which is hereby incorporated by reference.

In one or more embodiments of the present invention, the printing process may use an ink suitable for printing a patterned ink seed layer on the substrate. In one or more embodiments of the present invention, the ink may be a catalytic ink that serves as a base layer that can be electroless plated. In one or more embodiments of the present invention, the ink may be catalytic copper ink, nickel ink, silver ink, cobalt ink, zinc ink, gold ink, platinum ink, rhodium ink, or palladium ink. In one or more embodiments of the present invention, the ink may be a catalytic alloy ink that serves as a base layer that can be electroless plated. In one or more embodiments of the present invention, the ink may be a catalytic copper-nickel alloy, silver-indium alloy, silver-tin alloy, silver-copper alloy, copper-zinc alloy, copper-tin alloy, nickel-cobalt-iron alloy, or nickel-iron alloy. One of ordinary skill in the art will recognize that other catalytic inks and catalytic alloy inks are within the scope of one or more embodiments of the present invention.

In one or more embodiments of the present invention, the printed patterned ink seed layer includes a plurality of seed conductors suitable for electroless plating. In one or more embodiments of the present invention, the printed patterned ink seed conductors may be arranged in a micro mesh. In one or more embodiments of the present invention, the printed patterned ink seed conductors may be arranged in a micro mesh of row conductors and column conductors that are co-planar and perpendicular to one another. One of ordinary skill in the art will recognize that other micro mesh configurations are within the scope of one or more embodiments of the present invention.

In one or more embodiments of the present invention, the printed patterned ink seed conductors may have a thickness in a range between approximately 100 nanometers to approximately 300 nanometers. In one or more embodiments of the present invention, the printed patterned ink seed conductors may have a thickness greater than 300 nanometers. In one or more embodiments of the present invention, a thickness of the printed patterned ink seed conductors may be increased to improve the adhesion of plated metals to the substrate. In one or more embodiments of the present invention, a thickness of the printed patterned ink seed conductors may be increased to provide better control of plated metal thickness during an electroless plating process. In one or more embodiments of the present invention, the printed patterned ink seed conductors may have a thickness suitable to allow for thicker electroless copper plating. In one or more embodiments of the present invention, a width of the printed patterned ink seed conductors may be in a range between approximately 1 micron to approximately 9 microns. In one or more embodiments of the present invention, a width of the printed patterned ink seed conductors may be in a range between approximately 10 microns to approximately 20 microns. In one or more embodiments of the present invention, a width of the printed patterned ink seed conductors may be greater than 20 microns.

In step 320, electroless copper may be plated on the printed patterned ink seed layer. The copper may be plated on the printed patterned ink seed layer with a normal electroless copper plating process. The electroless copper plating process deposits a coating of copper on the printed patterned ink seed layer without the need for an electrode, which is required in electroplating. The electroless copper may be plated on top of the printed patterned ink seed layer in a pattern corresponding to the printed patterned ink seed layer. In one or more embodiments of the present invention, the metallization of the copper plating may be controlled to achieve a desired thickness. In one or more embodiments of the present invention, the electroless copper layer may have a thickness in a range between approximately 400 nanometers to approximately 500 nanometers. In one or more embodiments of the present invention, the electroless copper layer may have a thickness in a range between approximately 500 nanometers to approximately 700 nanometers. In one or more embodiments of the present invention, the electroless copper layer may have a thickness in a range between approximately 700 nanometers to approximately 2000 nanometers.

In step 330, the electroless copper plated substrate may be rinsed to remove chemicals that may adhere to the substrate during the electroless plating process. In one or more embodiments of the present invention, the electroless copper plated substrate may be dried to remove moisture from the substrate. Fine plated copper conductors have a number of undesirable features. Copper is not transparent or corrosion resistant. Copper easily forms an oxide layer upon exposure to the atmosphere. Copper is susceptible to scratching. The hue of copper shifts the color of the display and increases haze, negatively affecting display color quality. In addition, copper has poor bonding characteristics to metals used in flexible cables used for interconnects.

In step 340, a predetermined thickness of electroless nickel may be plated on the plated electroless copper in a pattern corresponding to the plated electroless copper and printed patterned ink seed layer with an electroless nickel plating process. In one or more embodiments of the present invention, the electroless nickel plating process may be compatible with the electroless copper plating process. In one or more embodiments of the present invention, the metallization of the nickel plating may be controlled to achieve a predetermined thickness. In one or more embodiments of the present invention, the electroless nickel layer may have a thickness in a range between approximately 20 nanometers to approximately 200 nanometers. In one or more embodiments of the present invention, the electroless nickel layer may have a thickness in a range between approximately 200 nanometers to approximately 2000 nanometers.

In one or more embodiments of the present invention, thin layers of electroless nickel plated on copper may improve transparency. In one or more embodiments of the present invention, copper-nickel micro mesh conductors improve visibility and reduce haze over copper conductors. In one or more embodiments of the present invention, thin layers of electroless nickel plated on copper improves corrosion resistance and scratch resistance. In one or more embodiments of the present invention, copper-nickel micro mesh conductors provide improved corrosion resistance and scratch resistance over copper conductors. In one or more embodiments of the present invention, thin layers of electroless nickel plated on copper reduces haze. In one or more embodiments of the present invention, copper-nickel micro mesh conductors provide improved haze and color quality over copper conductors.

In one or more embodiments of the present invention, the electroless nickel may be a nickel-boron alloy. The concentration of boron in the nickel-boron alloy may be varied to achieve different characteristics. A nickel-boron alloy with less than 1% concentration of boron provides increased solderability and ultrasonic bonding characteristics. A nickel-boron alloy with 2-3% concentration of boron provides increased hardness and wear resistance. A nickel-boron alloy with 3-5% boron concentration provides exceptionally high hardness and wear resistance, typically equal to that of chromium. In one or more embodiments of the present invention, the electroless nickel may be a nickel-phosphorus alloy. In one or more embodiments of the present invention, the electroless nickel may be any nickel alloy.

In step 350, the electroless copper-nickel plated substrate may be rinsed to remove chemicals that may adhere to the substrate during the electroless plating process. In one or more embodiments of the present invention, the electroless copper-nickel plated substrate may be dried to remove moisture from the substrate.

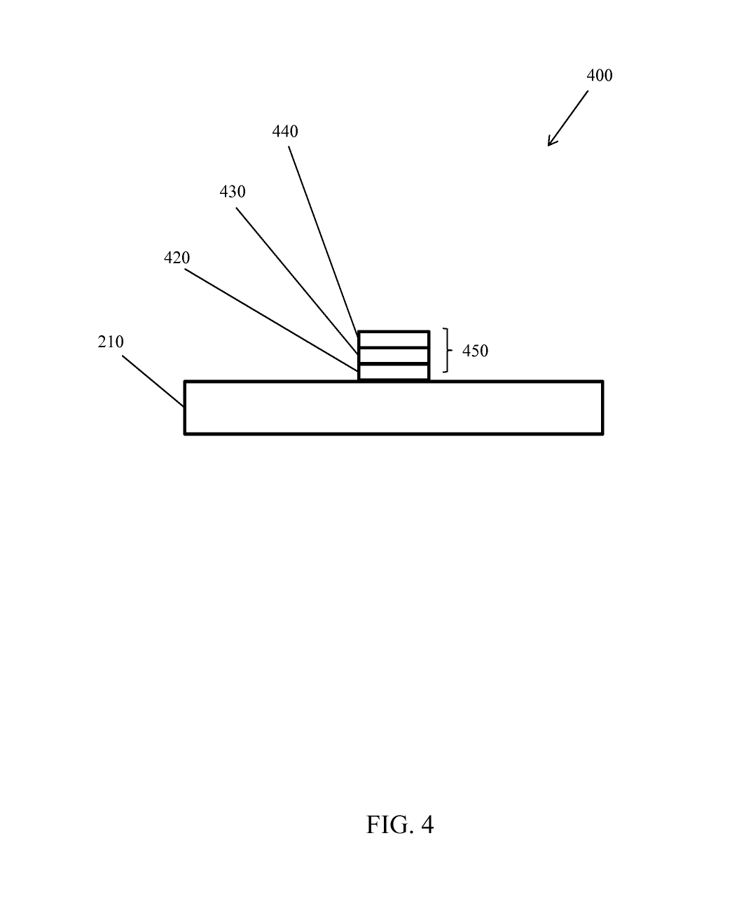

FIG. 4 shows a cross-section of a copper-nickel micro mesh conductor in accordance with one or more embodiments of the present invention. A copper-nickel micro mesh conductor 400 may be disposed on a substrate 210. In one or more embodiments of the present invention, substrate 210 may be a transparent substrate. In one or more embodiments of the present invention, substrate 210 may be a flexible substrate. A patterned ink seed conductor 420 may be printed on substrate 210. In one or more embodiments of the present invention, the printed patterned ink seed conductor 420 may have a thickness in a range between approximately 100 nanometers to 300 nanometers. In one or more embodiments of the present invention, the printed patterned ink seed conductor 420 may have a thickness greater than 300 nanometers. In one or more embodiments of the present invention, a thickness of the printed patterned ink seed conductors 420 may be increased to improve the adhesion of plated metals to the substrate. In one or more embodiments of the present invention, a thickness of the printed patterned ink seed conductors 420 may be increased to provide better control of plated metal thickness during an electroless plating process. In one or more embodiments of the present invention, the printed patterned ink seed conductors 420 may have a thickness suitable to allow for thicker electroless copper plating.

In one or more embodiments of the present invention, an electroless copper plated conductor 430 may be disposed on the printed patterned ink seed conductor 420. In one or more embodiments of the present invention, a thickness of the electroless copper plated conductor 430 may be controlled. In one or more embodiments of the present invention, the electroless copper plated conductor 430 may have a thickness in a range between approximately 400 nanometers to approximately 500 nanometers. In one or more embodiments of the present invention, the electroless copper plated conductor 430 may have a thickness in a range between approximately 500 nanometers to approximately 700 nanometers. In one or more embodiments of the present invention, the electroless copper plated conductor 430 may have a thickness in a range of approximately 700 nanometers to approximately 2000 nanometers. In one or more embodiments of the present invention, thicker printed patterned ink seed conductors 420 allow for improved control of plating thickness, leaving an un-plated layer between substrate 210 and the electroless plated copper conductor 430 resulting in a dark contrast from a viewer visible side facing substrate 210.

In one or more embodiments of the present invention, an electroless nickel plated conductor 440 may be disposed on the electroless copper plated conductor 430. In one or more embodiments of the present invention, the electroless nickel plated conductor 440 may have a predetermined thickness. In one or more embodiments of the present invention, the predetermined thickness of the electroless nickel plated conductor 440 may be in a range between approximately 20 nanometers to approximately 200 nanometers. In one or more embodiments of the present invention, the predetermined thickness of the electroless nickel plated conductor 440 may be in a range between approximately 200 nanometers to approximately 2000 nanometers. In one or more embodiments of the present invention, electroless nickel plated conductor 440 may encapsulate electroless copper plated conductor 430 providing sidewall coverage and protection from environmental degradation.

In one or more embodiments of the present invention, a width of copper-nickel micro mesh conductor 450 may be in a range between approximately 1 micron to approximately 9 microns. In one or more embodiments of the present invention, a width of copper-nickel micro mesh conductor 450 may be in a range between approximately 10 microns to approximately 20 microns. In one or more embodiments of the present invention, a width of copper-nickel micro mesh conductor 450 may be greater than 20 microns.

In one or more embodiments of the present invention, the width of copper-nickel micro mesh conductor 450, the thickness of the printed patterned ink seed conductor 420, the thickness of electroless copper plated conductor 430, and the thickness of electroless nickel plated conductor 440 may be varied to achieve one or more desired characteristics of the conductors. In one or more embodiments of the present invention, a taller aspect ratio, thickness to width, of copper-nickel micro mesh conductor 450 may provide improved electrical conductivity as the line width gets narrower.

The width of copper-nickel micro mesh conductor 450 may be varied to achieve a target electrical resistance and impacts transparency. The thickness of electroless copper plated conductor 430 may be varied to achieve a target electrical resistance. The thickness of electroless nickel plated conductor 440 may be varied to achieve a target corrosion resistance, scratch resistance, and transparency. Table 1 shows various combinations of electroless copper plated conductor 430 thickness and electroless nickel plated conductor 440 thickness in a copper-nickel micro mesh conductor 450 in accordance with one or more embodiments of the present invention.

TABLE 1

| Electroless Copper | Electroless Nickel | |
|---|---|---|
| Thickness | Thickness | Characteristics |
| 400-500 nm | 20-200 nm | Higher electrical resistance, |
| | | Lower corrosion resistance, |
| | | Lower scratch resistance, |
| | | Environmental resistance |
| 500-700 nm | 20-200 nm | Medium electrical resistance, |
| | | Lower corrosion resistance, |
| | | Lower scratch resistance, |
| | | Environmental resistance |
| 700-2000 nm | 20-200 nm | Lower electrical resistance, |
| | | Lower corrosion resistance, |
| | | Lower scratch resistance, |
| | | Environmental resistance |
| 400-500 nm | 200-2000 nm | Higher electrical resistance, |
| | | Higher corrosion resistance, |
| | | Higher scratch resistance, |
| | | Environmental resistance |
| 500-700 nm | 200-2000 nm | Medium electrical resistance, |
| | | Higher corrosion resistance, |
| | | Higher scratch resistance, |
| | | Environmental resistance |
| 700-2000 nm | 200-2000 nm | Lower electrical resistance, |
| | | Higher corrosion resistance, |
| | | Higher scratch resistance, |
| | | Environmental resistance |

Advantages of one or more embodiments of the present invention may include one or more of the following:

In one or more embodiments of the present invention, copper-nickel micro mesh conductors eliminate the need for ITO conductors in a touch sensor.

In one or more embodiments of the present invention, copper-nickel micro mesh conductors provide micron-fine conductors with high conductivity and high transparency.

In one or more embodiments of the present invention, copper-nickel micro mesh conductors reduce the haze of a touch sensor.

In one or more embodiments of the present invention, copper-nickel micro mesh conductors improve the transparency of a touch sensor.

In one or more embodiments of the present invention, copper-nickel micro mesh conductors improve the corrosion resistance of a touch sensor.

In one or more embodiments of the present invention, copper-nickel micro mesh conductors improve the scratch resistance of a touch sensor.

In one or more embodiments of the present invention, copper-nickel micro mesh conductors improve the scan rate of a touch sensor.

In one or more embodiments of the present invention, copper-nickel micro mesh conductors reduce the electrical resistance of a touch sensor.

In one or more embodiments of the present invention, copper-nickel micro mesh conductors provide improved electrical conductivity.

In one or more embodiments of the present invention, copper-nickel micro mesh conductors are more power efficient than conventional touch sensor conductors.

In one or more embodiments of the present invention, copper-nickel micro mesh conductors enhance the bonding characteristics for circuit connections.

In one or more embodiments of the present invention, copper-nickel micro mesh conductors provide environmental degradation resistance.

In one or more embodiments of the present invention, copper-nickel micro mesh conductors provide improved electromagnetic interference-radio frequency interference shielding compared to conventional touch sensor conductors.

In one or more embodiments of the present invention, copper-nickel micro mesh conductors eliminate the need for a shielding layer between the display device and the touch sensor.

In one or more embodiments of the present invention, copper-nickel micro mesh conductors are less expensive to fabricate than conventional touch sensor conductors.

In one or more embodiments of the present invention, copper-nickel micro mesh conductors are easier to fabricate than conventional touch sensor conductors.

In one or more embodiments of the present invention, copper-nickel micro mesh conductors may be produced using roll-to-roll printing processes instead of expensive batch processes.

In one or more embodiments of the present invention, copper-nickel micro mesh conductors allow for the production of larger touch sensors and touch screens.

In one or more embodiments of the present invention, copper-nickel micro mesh conductors reduce the assembly cost of the touch screen.

In one or more embodiments of the present invention, copper-nickel micro mesh conductors reduces the weight of the touch screen.

In one or more embodiments of the present invention, copper-nickel micro mesh conductors are Restriction of Hazardous Substances (“RoHS”) compliant and more environmentally friendly.

In one or more embodiments of the present invention, copper-nickel micro mesh conductors may be used to form an antenna.

In one or more embodiments of the present invention, copper-nickel micro mesh conductors may be used to form a transparent antenna.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A method of fabricating copper-nickel micro mesh conductors comprising:
printing a patterned ink seed layer on a substrate;
plating electroless copper on the printed patterned ink seed layer; and
plating a predetermined thickness of electroless nickel on the plated electroless copper.

2. The method of claim 1, wherein the predetermined thickness is in a range between approximately 20 nanometers to approximately 200 nanometers.

3. The method of claim 1, wherein the predetermined thickness is in a range of between approximately 200 nanometers to approximately 2000 nanometers.

4. The method of claim 1, wherein a thickness of the plated electroless copper is in a range between approximately 400 nanometers to approximately 500 nanometers.

5. The method of claim 1, wherein a thickness of the plated electroless copper is in a range between approximately 500 nanometers to approximately 700 nanometers.

6. The method of claim 1, wherein a thickness of the plated electroless copper is in a range between approximately 700 nanometers to approximately 2000 nanometers.

7. The method of claim 1, wherein the copper-nickel micro mesh conductors have a width in a range between approximately 1 micron and approximately 9 microns.

8. The method of claim 1, wherein the copper-nickel micro mesh conductors have a width in a range between approximately 10 micron and approximately 20 microns.

9. The method of claim 1, wherein the copper-nickel micro mesh conductors have a width in a range greater than approximately 20 microns.

10. The method of claim 1, wherein the electroless nickel comprises a nickel-boron alloy.

11. The method of claim 1, wherein the electroless nickel comprises a nickel-phosphorus alloy.

12. The method of claim 1, wherein the patterned ink seed layer comprises a micro mesh of seed conductors.

13. The method of claim 1, wherein the ink comprises a catalytic ink.

14. The method of claim 1, wherein the substrate comprises a polyethylene terephthalate substrate.

15. A touch sensor comprising:
a substrate;
a patterned ink seed layer printed on the substrate;
an electroless copper plating layer disposed on the printed patterned ink seed layer; and
an electroless nickel plating layer having a predetermined thickness disposed on the electroless copper plating layer.

16. The touch sensor of claim 15, wherein the predetermined thickness is in a range between approximately 20 nanometers to approximately 200 nanometers.

17. The touch sensor of claim 15, wherein the predetermined thickness is in a range of between approximately 200 nanometers to approximately 2000 nanometers.

18. The touch sensor of claim 15, wherein a thickness of the plated electroless copper is in a range between approximately 400 nanometers to approximately 500 nanometers.

19. The touch sensor of claim 15, wherein a thickness of the plated electroless copper is in a range between approximately 500 nanometers to approximately 700 nanometers.

20. The touch sensor of claim 15, wherein a thickness of the plated electroless copper is in a range between approximately 700 nanometers to approximately 2000 nanometers.

21. The touch sensor of claim 15, wherein the plated electroless copper-nickel has a width in a range between approximately 1 micron and approximately 9 microns.

22. The touch sensor of claim 15, wherein the plated electroless copper-nickel has a width in a range between approximately 10 micron and approximately 20 microns.

23. The touch sensor of claim 15, wherein the plated electroless copper-nickel has a width in a range greater than approximately 20 microns.

24. The touch sensor of claim 15, wherein the electroless nickel comprises a nickel-boron alloy.

25. The touch sensor of claim 15, wherein the electroless nickel comprises a nickel-phosphorus alloy.

26. The touch sensor of claim 15, wherein the patterned ink seed layer comprises a micro mesh of seed conductors.

27. The touch sensor of claim 15, wherein the ink comprises a catalytic ink.

28. The touch sensor of claim 15, wherein the substrate comprises a polyethylene terephthalate substrate.
